(19) United States
(12) Patent Application Publication
(10) Pub. No.: US 2023/0261224 A1
(43) Pub. Date: Aug. 17, 2023

(54) Apparatus for Converting Power of Fuel Cell for Power Generation and Method Thereof

(71) Applicants: Hyundai Motor Company, Seoul (KR); Kia Corporation, Seoul (KR)

(72) Inventors: Yong Doo Son, Incheon (KR); Jung Tak Kang, Incheon (KR)

(21) Appl. No.: 18/049,745

(22) Filed: Oct. 26, 2022

(30) Foreign Application Priority Data
Feb. 16, 2022 (KR) 10-2022-0020372

(51) Int. Cl. H01M 8/04537; H01M 8/04302; H01M 8/04858

(52) U.S. Cl. CPC H01M 8/04611; H01M 8/04552; H01M 8/04302; H01M 8/04932; H01M 8/04902

(57) ABSTRACT

An apparatus for converting power of a fuel cell for power generation to remove an open voltage of the fuel cell and a method thereof are provided. A controller links current to a system or load to reduce an open circuit voltage (OCV) of the fuel cell before power generation of the fuel cell is started, after the fuel cell is started. A power converter converts and supplies power generated by the fuel cell to the system or load. The apparatus removes an OCV of a fuel cell stack to prevent performance and life of the fuel cell from being reduced.

### CROSS-REFERENCE TO RELATED APPLICATION

This application claims the benefit of priority to Korean Patent Application No. 10-2022-0020372, filed in the Korean Intellectual Property Office on Feb. 16, 2022, the entire contents of which are incorporated herein by reference.

### TECHNICAL FIELD

The present disclosure relates to an apparatus for converting power of a fuel cell for power generation and a method thereof, and more particularly, relates to an apparatus for converting power of a fuel cell for power generation to remove an open voltage of the fuel cell when the fuel cell is driven and a method thereof.

### BACKGROUND

A fuel cell system generates power using hydrogen or the like. In general, the fuel cell system includes a fuel cell stack in which a plurality of fuel cells are laminated. When there is an open circuit voltage (OCV) when the fuel cell stack is driven, performance and life of the fuel cell may be reduced. There is a scheme of bucking voltage using a resistor as an existing scheme of removing an OCV of the fuel cell. However, when the scheme using the resistor is used, as a passive element is used, it is difficult to adjust a bucking degree as the capacity of the resistor is large, heating occurs, and performance of the stack is reduced. Furthermore, when voltage introduced into the resistor is adjusted through switching, as a ripple current is introduced into a stack, a direct current/direct current (DC/DC) converter, or a direct current/alternating current (DC/AC) inverter, voltage quality is reduced.

Furthermore, it is possible to remove an OCV using a charging function of a high voltage battery in a fuel cell vehicle. However, when the high voltage battery is used, a separate battery and a charging and discharging device may be required and a control process thereof may be complicated. In addition, because a stack and a load (or a system) are connected one to one in a fuel cell for power generation, it is impossible to control an OCV. Thus, there is a need to develop a technology for addressing such problems and controlling an OCV of the fuel cell.

### SUMMARY

The present disclosure has been made to solve the above-mentioned problems occurring in the prior art while advantages achieved by the prior art are maintained intact.

An aspect of the present disclosure provides an apparatus for converting power of a fuel cell for power generation to remove an open voltage of the fuel cell and a method thereof.

Another aspect of the present disclosure provides an apparatus for converting power of a fuel cell for power generation to address a problem in which it is impossible to control an open voltage, because a stack and a load (a system) are connected one to one in the fuel cell for power generation and a method thereof.

Another aspect of the present disclosure provides an apparatus for converting power of a fuel cell for power generation to control an open circuit voltage (OCV) of a fuel cell stack without a separate battery and a method thereof.

Another aspect of the present disclosure provides an apparatus for converting power of a fuel cell for power generation to minimize heating due to a resistor to remove an open voltage of the fuel cell and a method thereof.

Another aspect of the present disclosure provides an apparatus for converting power of a fuel cell for power generation to prevent performance and life of the fuel cell from being reduced and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus for converting power of a fuel cell for power generation may include a power converter that converts and supplies power generated by the fuel cell to a system or load and a controller that links current to the system or load to reduce an open circuit voltage (OCV) of the fuel cell before power generation of the fuel cell is started, after the fuel cell is started.

In an embodiment, the controller may check a state of the system or load, before linking the current to the system or load and may link the current to the system or load, when it is determined that there is no abnormality in the system or load.

In an embodiment, the controller may monitor the OCV of the fuel cell and may increase current linked to the system or load such that the OCV of the fuel cell is less than a reference voltage.

In an embodiment, the controller may link the current to the system or load by controlling a switching element connected with an input terminal and an output terminal of the power converter to be turned on.

In an embodiment, the apparatus may further include a first initial charge circuit connected in parallel between an output terminal of the fuel cell and an input terminal of the power converter to cut off an inrush current from the fuel cell.

In an embodiment, the apparatus may further include a second initial charge circuit connected in series between an output terminal of the power converter and the system or load to cut off an inrush current to the system or load.

In an embodiment, the controller may operate the first initial charge circuit to reduce the OCV of the fuel cell, after controlling a switching element connected with the input terminal of the power converter to be turned on.

In an embodiment, the power converter may include a direct current/alternating current (DC/AC) inverter that converts DC power generated by the fuel cell into AC power.

In an embodiment, the apparatus may further include a filter device connected with an output terminal of the power converter to remove a noise of power output from the power converter.

In an embodiment, the switching element may include a magnetic contactor (MC).

According to another aspect of the present disclosure, a method for converting power of a fuel cell for power generation may include linking, by a controller, a current to a system or load to reduce an OCV of the fuel cell before power generation of the fuel cell is started, after the fuel cell is started, and converting and supplying, by a power converter, power generated by the fuel cell to the system or load.

In an embodiment, the linking of the current to the system or load to reduce the OCV of the fuel cell by the controller may include checking, by the controller, a state of the system or load, before linking the current to the system or load, and linking the current to the system or load, when it is determined that there is no abnormality in the system or load.

In an embodiment, the linking of the current to the system or load to reduce the OCV of the fuel cell by the controller may include monitoring, by the controller, the OCV of the fuel cell and increasing, by the controller, current linked to the system or load such that the OCV of the fuel cell is less than a reference voltage.

In an embodiment, the linking of the current to the system or load to reduce the OCV of the fuel cell by the controller may include linking, by the controller, the current to the system or load by controlling, by the controller, a switching element connected with an input terminal and an output terminal of the power converter to be turned on.

In an embodiment, the method may further include cutting off, by a first initial charge circuit connected in parallel between an output terminal of the fuel cell and an input terminal of the power converter, an inrush current from the fuel cell.

In an embodiment, the method may further include cutting off, by a second initial charge circuit connected in series between an output terminal of the power converter and the system or load, an inrush current to the system or load.

In an embodiment, the method may further include operating the first initial charge circuit to reduce the OCV of the fuel cell, after controlling a switching element connected with the input terminal of the power converter to be turned on.

In an embodiment, the converting and supplying of the power generated by the fuel cell to the system or load by the power converter may include converting, by the power converter, DC power generated by the fuel cell into AC power by a DC/AC inverter.

In an embodiment, the method may further include removing, by a filter device connected with an output terminal of the power converter, a noise of power output from the power converter.

In an embodiment, the linking of the current to the system or load by the controller by controlling, by the controller, the switching element connected with the input terminal and the output terminal of the power converter to be turned on may include linking, by the controller, the current to the system or load by controlling, by the controller, a magnetic contactor (MC) connected with the input terminal and the output terminal of the power converter to be turned on.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating an apparatus for converting power of a fuel cell for power generation according to an embodiment of the present disclosure;

FIG. 2 is a drawing illustrating a detailed configuration of an apparatus for converting power of a fuel cell for power generation according to an embodiment of the present disclosure;

FIG. 3 is a flowchart illustrating an operation of an existing apparatus for converting power of a fuel cell for power generation;

FIG. 4 is a flowchart illustrating an operation of an apparatus for converting power of a fuel cell for power generation according to an embodiment of the present disclosure;

FIG. 5A is a drawing illustrating various signals according to an operation of an existing apparatus for converting power of a fuel cell for power generation;

FIG. 5B is a drawing illustrating various signals according to an operation of an apparatus for converting power of a fuel cell for power generation according to an embodiment of the present disclosure;

FIG. 6 is a flowchart illustrating a method for converting power of a fuel cell for power generation according to an embodiment of the present disclosure; and

FIG. 7 is a block diagram illustrating a computing system according to an embodiment of the present disclosure.

### DETAILED DESCRIPTION

Hereinafter, some embodiments of the present disclosure will be described in detail with reference to the exemplary drawings. In the drawings, the same reference numerals will be used throughout to designate the same or equivalent elements. In addition, a detailed description of well-known features or functions will be ruled out in order not to unnecessarily obscure the gist of the present disclosure.

In describing the components of the embodiment according to the present disclosure, terms such as first, second, “A”, “B”, (a), (b), and the like may be used. These terms are only used to distinguish one element from another element, but do not limit the corresponding elements irrespective of the order or priority of the corresponding elements. Furthermore, unless otherwise defined, all terms including technical and scientific terms used herein are to be interpreted as is customary in the art to which this disclosure belongs. Such terms as those defined in a generally used dictionary are to be interpreted as having meanings equal to the contextual meanings in the relevant field of art, and are not to be interpreted as having ideal or excessively formal meanings unless clearly defined as having such in the present application.

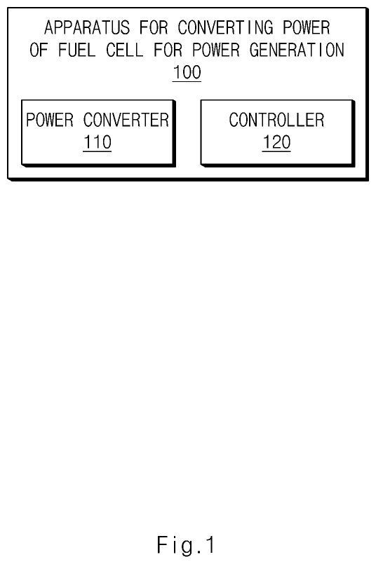

Hereinafter, embodiments of the present disclosure will be described in detail with reference to FIGS. 1 to 7.

FIG. 1 is a block diagram illustrating an apparatus for converting power of a fuel cell for power generation according to an embodiment of the present disclosure.

An apparatus 100 for converting power of a fuel cell for power generation according to an embodiment of the present disclosure may be implemented by being connected with an output terminal of a fuel cell system.

Referring to FIG. 1, the apparatus 100 for converting the power of the fuel cell for power generation may include a power converter 110 and a controller 120.

The power converter 110 may convert and supplies power generated by means of the fuel cell to a system or load.

As an example, the power converter 110 may include a DC/AC inverter which converts DC power generated by means of the fuel cell into AC power.

Because DC power is generated from the fuel cell, there is a need to convert the generated DC power into AC power to transfer the generated DC power to the system or load.

As an example, an input terminal of the power converter 110 may be connected with the fuel cell, and an output terminal of the power converter 110 may be connected with the system or load.

A switching element controlled by the controller 120 may be connected with the input terminal and the output terminal of the power converter 110. Thus, a connection between the power converter 110 and the fuel cell and a connection between the power converter 110 and the system or load may be selectively controlled by the controller 120.

As an example, the switching element connected with the input terminal and the output terminal of the power converter 110 or a switching element which turns on or off a connection of a first initial charge circuit which will be described below may include a magnetic contactor (MC).

As another example, the switching element connected with the input terminal and the output terminal of the power converter 110 or the switching element which turns on or off the connection of the first initial charge circuit which will be described below may include a circuit breaker or another type of switching element.

Although not illustrated, as an example, the apparatus 100 for converting the power of the fuel cell for power generation may further include the first initial charge circuit connected in parallel between the output terminal of the fuel cell and the input terminal of the power converter 110 to cut off an inrush current from the fuel cell.

As an example, the first initial charge circuit may include one or more resistance element and a capacitance element.

As an example, the first initial charge circuit may include a switching element which turns on or off a connection of the first initial charge circuit. The switching element which turns on or off the connection of the first initial charge circuit may be controlled by the controller 120.

Although not illustrated, as an example, the apparatus 100 for converting the power of the fuel cell for power generation may further include a second initial charge circuit connected in series between the output terminal of the power converter 110 and the system or load to cut off an inrush current to the system or load.

As an example, the second initial charge circuit may include one or more resistance element and a capacitance element.

As an example, because the second initial charge circuit is connected in series between the output terminal of the power converter 110 and the system or load, when the switching element connected with the output terminal of the power converter 110 is turned on, the second initial charge circuit may operate automatically to cut off an inrush current to the system or load.

Although not illustrated, as an example, the apparatus 100 for converting the power of the fuel cell for power generation may further include a filter device connected with the output terminal of the power converter 110 to remove a noise of power output from the power converter 110.

As an example, the filter device may include an electro magnetic interference (EMI) filter which removes or reduces noise, or the like.

The controller 120 may include one or more processors which perform data processing and/or calculation which will be described below. Furthermore, the controller 120 may include a memory which stores data or an algorithm required in a process of performing data processing and/or calculation.

The controller 120 may perform the overall control such that respective components may normally perform their own functions. Such a controller 120 may be implemented in the form of hardware, may be implemented in the form of software, or may be implemented in the form of a combination thereof. Preferably, the controller 120 may be implemented as, but not limited to, one or more microprocessors.

The memory capable of being included in the controller 120 may include at least one type of storage medium, such as a flash memory type memory, a hard disk type memory, a micro type memory, a card type memory (e.g., a secure digital (SD) card or an extreme digital (XD) card), a random access memory (RAM), a static RAM (SRAM), a read-only memory (ROM), a programmable ROM (PROM), an electrically erasable PROM (EEPROM), a magnetic RAM (MRAM), a magnetic disk, or an optical disk.

As an example, the controller 120 may be connected with the power converter 110, the first initial charge circuit, the second initial charge circuit, the filter device, or the like and may output and deliver a signal for controlling each component.

As an example, the controller 120 may control on or off of the switching element connected with the input terminal and the output terminal of the power converter 110 or the switching element which turns on or off the connection of the first initial charge circuit.

The controller 120 may link current to the system or load to reduce an open circuit voltage (OCV) of the fuel cell before power generation of the fuel cell is started, after the fuel cell is started.

When current output from the fuel cell is connected with the system or load before power generation of the fuel cell is started, after the fuel cell is started, the OCV of the fuel cell may be reduced due to a voltage drop through the system or load.

As an example, the controller 120 may link current to the system or load by controlling the switching element connected with the input terminal and the output terminal of the power converter 110 to be turned on.

When the switching element connected with the input terminal and the output terminal of the power converter 110 is controlled to be turned on, current output from the fuel cell may be connected with the system or load.

As an example, the controller 120 may check a state of the system or load, before linking current to the system or load, and may link the current to the system or load, when it is determined that there is no abnormality in the system or load.

When it is determined that there is no abnormality in the system or load after the checking of the load of the system or load is completed, safety issues do not occur, although a current of the fuel cell is linked to the system or load in advance before main power generation of the fuel cell is initiated.

As an example, the controller 120 may include a system monitoring device for checking a state of the system or load.

As another example, the controller 120 may receive information about a state of the system or load from a component which checks the state of the system or load on its own and may determine whether there is an abnormality in the system or load.

As an example, the controller 120 may monitor an OCV of the fuel cell and may increase current linked to the system or load such that the OCV of the fuel cell is less than a reference voltage.

As an example, the controller 120 may measure a voltage of the output terminal of the fuel cell to monitor the OCV of the fuel cell.

As another example, the controller 120 may receive information about the OCV of the fuel cell from a component loaded into the fuel cell system to measure the OCV of the fuel cell and may monitor the OCV of the fuel cell.

When current linked to the system or load increases, as a voltage drop through the system or load increases, the OCV of the fuel cell may decrease more.

As an example, the reference voltage may be predetermined to a value small enough to be determined that the OCV of the fuel cell is not present.

As an example, after current starts to be linked from the fuel cell to the system or load, when the linked current increases and the OCV of the fuel cell is less than the reference voltage, the controller 120 may determine that the removal of the OCV is completed and may initiate main power generation through the fuel cell.

As an example, after controlling the switching element connected with the input terminal of the power converter 110 to be turned on, the controller 120 may operate the first initial charge circuit operate to reduce an OCV of the fuel cell.

When the first initial charge circuit is operated, as a voltage drop by a resistance element or a capacitance element included in the first initial charge circuit occurs, the OCV of the fuel cell may be reduced.

As an example, the controller 120 may turn on the switching element connected with the first initial charge circuit to operate the first initial charge circuit, thus reducing the OCV of the fuel cell.

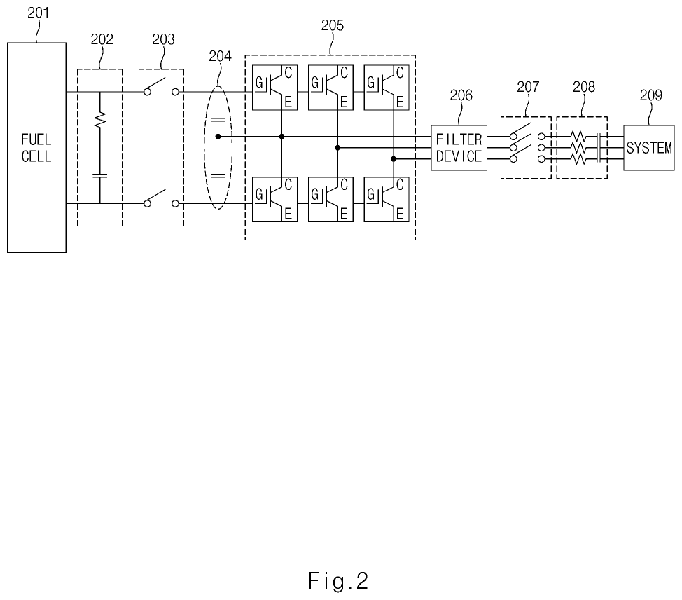

FIG. 2 is a drawing illustrating a detailed configuration of an apparatus for converting power of a fuel cell for power generation according to an embodiment of the present disclosure.

Referring to FIG. 2, a first initial charge circuit 202 may be connected in parallel with an output terminal of a fuel cell 201.

The first initial charge circuit 202 may cut off an inrush current in a process where DC power output through the fuel cell 201 is delivered to a power converter 205.

A DC input breaker 203 connected between an input terminal of the power converter 205 and the fuel cell 201 may connect or block an input of the power converter 205.

As an example, the DC input breaker 203 may include a magnetic contactor (MC).

As an example different from the example shown in the drawing, the DC input breaker 203 may be located at the fuel cell 201 rather than the first initial charge circuit 202.

Furthermore, although not illustrated, as an example, a DC/DC converter may be connected between the fuel cell 201 and the power converter 205 to convert an output of the fuel cell 201.

A DC link voltage may refer to a voltage of a portion 204 with which the input terminal of the power converter 205 and the DC input breaker 203 are connected.

The power converter 205 may convert DC power at the fuel cell 201 into AC power and may supply the AC power to a system 209.

A filter device 206 connected with the output terminal of the power converter 205 may remove a noise of power output from the output terminal.

An AC system breaker 207 connected with the output terminal of the power converter 205 may connect or cut off supply of the converted AC power to or from the system 209.

As an example, the AC system breaker 207 may include a magnetic contactor (MC).

A second initial charge circuit 208 may be connected in series with the output terminal of the power converter 205.

The second initial charge circuit 208 may include a resistance element and a capacitance element and may cut off an inrush current in a process where AC power output through the power converter 205 is delivered to the system 209.

Although not illustrated, as an example, a system monitoring device for identifying whether there is a failure or an abnormality in the system 209 may be connected with the system 209.

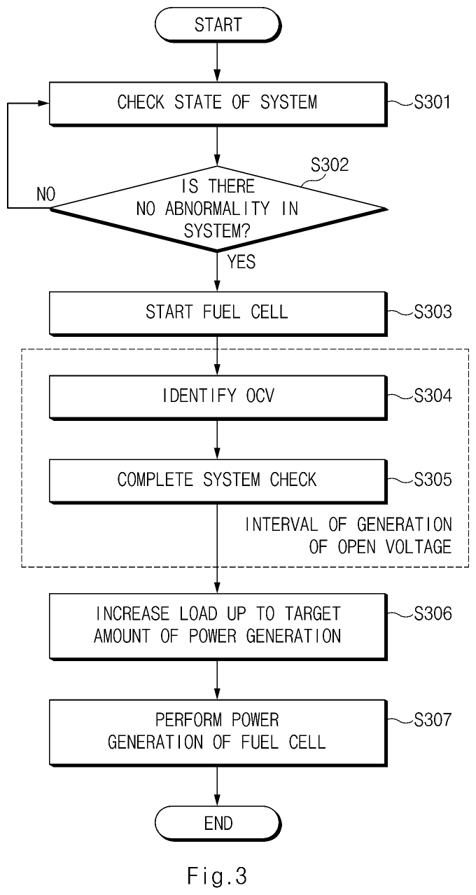

FIG. 3 is a flowchart illustrating an operation of an existing apparatus for converting power of a fuel cell for power generation.

Referring to FIG. 3, in S301, the existing apparatus for converting the power of the fuel cell for power generation may check a state of a system.

In S302, the existing apparatus for converting the power of the fuel cell for power generation may identify whether there is no abnormality in the system.

As an example, the existing apparatus for converting the power of the fuel cell for power generation may diagnose whether there is no failure or abnormality in a system or load which is a target to which power output from the fuel cell is converted and supplied.

When there is the abnormality in the system, the existing apparatus for converting the power of the fuel cell for power generation may return to S301 to check the state of the system.

When there is no abnormality in the system, in S303, the existing apparatus for converting the power of the fuel cell for power generation may start the fuel cell.

When the fuel cell is started, as an OCV is generated, a fuel cell stack may be damaged.

In S304, the existing apparatus for converting the power of the fuel cell for power generation may identify the OCV of the fuel cell.

In S305, the existing apparatus for converting the power of the fuel cell for power generation may complete the system check.

Although the OCV of the fuel cell is generated in S304 and S305, the existing apparatus for converting the power of the fuel cell for power generation may perform power conversion without an operation of removing the OCV.

In S306, the existing apparatus for converting the power of the fuel cell for power generation may increase a load up to the target amount of power generation.

The OCV of the fuel cell may be present before the fuel cell and the system or load are linked to each other in the process where the existing apparatus for converting the power of the fuel cell for power generation increases the load up to the target amount of power generation.

In S307, the existing apparatus for converting the power of the fuel cell for power generation may perform main power generation of the fuel cell.

As an example, when the load increases up to the target amount of power generation, the existing apparatus for converting the power of the fuel cell for power generation may convert and deliver power, output from the fuel cell, to the system.

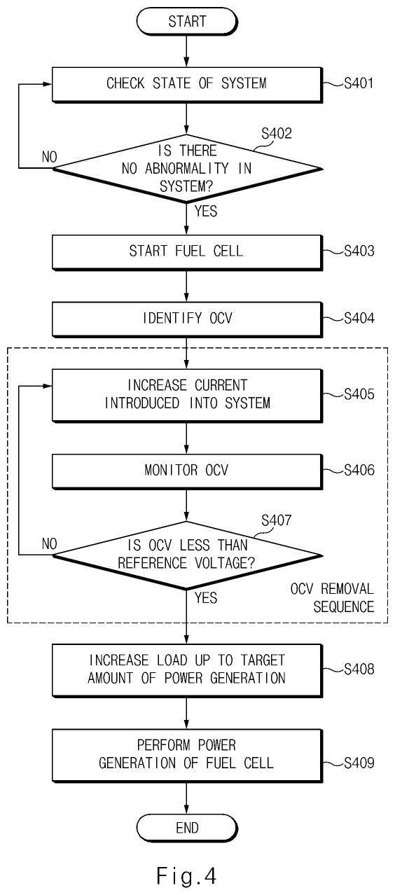

FIG. 4 is a flowchart illustrating an operation of an apparatus for converting power of a fuel cell for power generation according to an embodiment of the present disclosure.

Referring to FIG. 4, in S401, the apparatus for converting the power of the fuel cell for power generation may check a state of a system.

In S402, the apparatus for converting the power of the fuel cell for power generation may identify whether there is no abnormality in the system.

When there is no abnormality in the system, in S403, the apparatus for converting the power of the fuel cell for power generation may start the fuel cell.

The operation performed in S401 to S403 by the apparatus for converting the power of the fuel cell for power generation may be the same as an operation performed in S301 to S303 of FIG. 3 by an existing apparatus for converting power of a fuel cell for power generation.

In S404, the apparatus for converting the power of the fuel cell for power generation may check an OCV of the fuel cell.

As an example, the apparatus for converting the power of the fuel cell for power generation may identify whether the OCV of the fuel cell is greater than a reference voltage. When the OCV of the fuel cell is greater than the reference voltage, the apparatus for converting the power of the fuel cell for power generation may determine that the OCV of the fuel cell is present.

In S405, the apparatus for converting the power of the fuel cell for power generation may increase current introduced into the system.

As an example, the apparatus for converting the power of the fuel cell for power generation may connect a switching element with opposite ends of a power converter, such that current is linked from the fuel cell to the system or load, thus increasing current introduced into the system or load.

In S406, the apparatus for converting the power of the fuel cell for power generation may monitor an OCV of the fuel cell.

As an example, the apparatus for converting the power of the fuel cell for power generation may monitor the OCV of the fuel cell in real time, while increasing current introduced into the system or load.

In S407, the apparatus for converting the power of the fuel cell for power generation may identify whether the OCV is less than the reference voltage.

As an example, the apparatus for converting the power of the fuel cell for power generation may determine whether the OCV is present, depending on whether the OCV is less than the reference voltage.

When the OCV is not less than the reference voltage, the apparatus for converting the power of the fuel cell for power generation may return to S405 to increase current introduced into the system.

When the OCV is less than the reference voltage, in S408, the apparatus for converting the power of the fuel cell for power generation may increase the load up to the target amount of power generation.

After it is identified that the OCV is less than the reference voltage, because the load increases up to the target amount of power generation, the OCV may be removed before main power generation of the fuel cell is performed.

In S409, the apparatus for converting the power of the fuel cell for power generation may perform the main power generation of the fuel cell.

As an example, when the load increases up to the target amount of power generation, the apparatus for converting the power of the fuel cell for power generation may convert and deliver power, output from the fuel cell, to the system.

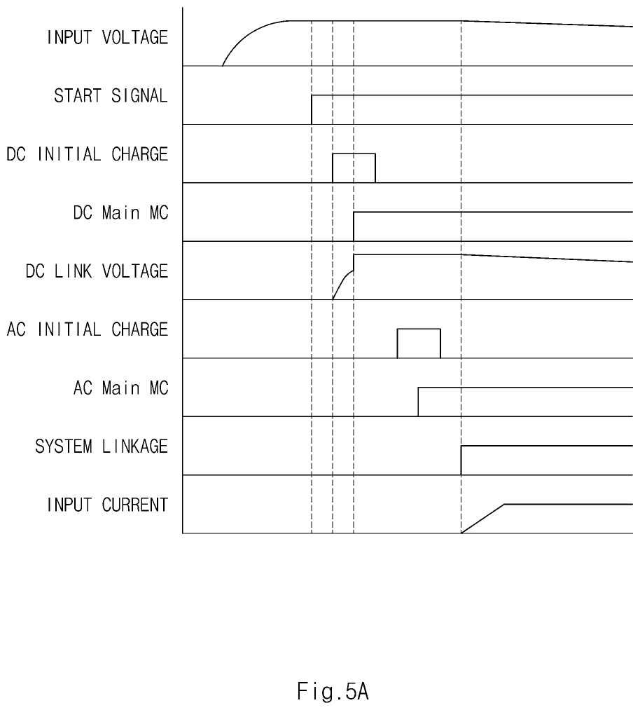

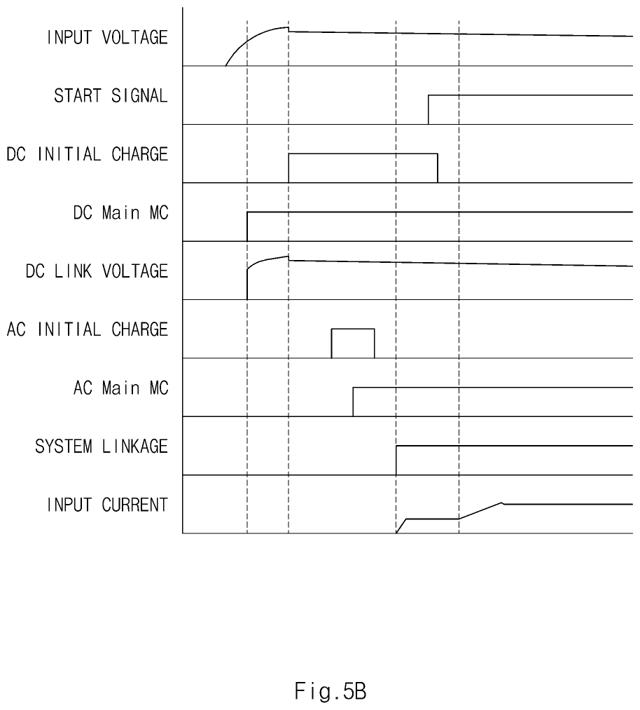

FIG. 5A is a drawing illustrating various signals according to an operation of an existing apparatus for converting power of a fuel cell for power generation.

Referring to FIG. 5A, after an input voltage first increases, a power generation start signal may be generated.

As an example, the power generation start signal may be output by a controller of the existing apparatus for converting the power of the fuel cell for power generation and may be delivered to a fuel cell system.

In response to the power generation start signal, main power generation of the fuel cell may be initiated.

After the power generation start signal is generated, as DC initial charge is performed, a DC link voltage may increase.

The DC link voltage may refer to a voltage of a portion in which an input terminal of the power converter and a DC initial charge circuit or a DC main magnetic contactor are connected with each other.

By the existing apparatus for converting the power of the fuel cell for power generation, after DC initial charge is performed, as the DC main magnetic contactor is turned on, the fuel cell and the power converter may be connected with each other.

The DC main magnetic contactor may serve as a switching element which turns on or off a connection between the power converter and the fuel cell.

Furthermore, by the existing apparatus for converting the power of the fuel cell for power generation, after the DC main magnetic contactor is turned on, AC initial charge may be performed, and then in turn, the AC main magnetic contactor may be turned on, the system may be linked, and an input current may be generated.

The input current may refer to current delivered to the system.

The AC main magnetic contactor may serve as a switching element which turns on or off a connection between the power converter and the system.

As an example, control of the DC initial charge, the DC main magnetic contactor, the AC initial charge, and the AC main magnetic contactor may be performed by a controller of the existing apparatus for converting the power of the fuel cell for power generation.

According to a topology and a control order of the existing apparatus for converting the power of the fuel cell for power generation, as current is linked to the system after the main power generation of the fuel cell is started, an OCV of the fuel cell, which is generated before the main power generation is initiated, is not removed.

FIG. 5B is a drawing illustrating various signals according to an operation of an apparatus for converting power of a fuel cell for power generation according to an embodiment of the present disclosure.

Referring to FIG. 5B, by the apparatus for converting the power of the fuel cell for power generation according to an embodiment of the present disclosure, after an input voltage first increases, a DC main magnetic contactor may be turned on and a DC link voltage may increase.

The input voltage may refer to a voltage of an output terminal of the fuel cell.

The DC link voltage may refer to a voltage of a portion in which an input terminal of the power converter and a DC initial charge circuit or a DC main magnetic contactor are connected with each other.

The DC main magnetic contactor may serve as a switching element which turns on or off a connection between the power converter and the fuel cell.

By the apparatus for converting the power of the fuel cell for power generation according to an embodiment of the present disclosure, after the DC main magnetic contactor is turned on, DC initial charge may be performed, and then in turn, AC initial charge may be performed, the AC main magnetic contactor may be turned on, the system may be linked, and an input current may be generated.

The AC main magnetic contactor may serve as a switching element which turns on or off a connection between the power converter and the system.

The input current may refer to current delivered to the system.

According to another embodiment, unlike those shown in the graph, DC initial charge may first be performed, and the DC main magnetic contactor may then be turned on. Alternatively, DC initial charge and on of the DC main magnetic contactor may be performed at the same time.

Furthermore, According to another embodiment, unlike those shown in the graph, AC initial charge may first be performed, and the AC main magnetic contactor may then be turned on. Alternatively, AC initial charge and on of the AC main magnetic contactor may be performed at the same time.

When current is linked to the system, an OCV of the fuel cell may decrease.

After the OCV of the fuel cell decreases, as a power generation start signal is generated, main power generation of the fuel cell may be initiated.

As an example, the power generation start signal may be output by a controller of the apparatus for converting the power of the fuel cell for power generation according to an embodiment of the present disclosure and may be delivered to a fuel cell system.

As an example, control of the DC initial charge, the DC main magnetic contactor, the AC initial charge, and the AC main magnetic contactor may be performed by the controller of the apparatus for converting the power of the fuel cell for power generation according to an embodiment of the present disclosure.

According to a topology and a control order of the apparatus for converting the power of the fuel cell for power generation according to an embodiment of the present disclosure, after current is linked to the system, as the main power generation of the fuel cell is initiated, an OCV of the fuel, which is generated before the main power generation is initiated, may be removed.

The apparatus for converting the power of the fuel cell for power generation according to an embodiment of the present disclosure may change only a control order without correcting the hardware or topology of the existing apparatus for converting the power of the fuel cell for power generation to remove an OCV of the fuel cell.

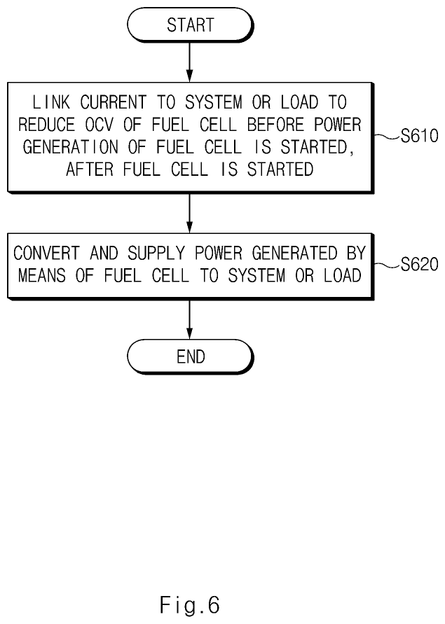

FIG. 6 is a flowchart illustrating a method for converting power of a fuel cell for power generation according to an embodiment of the present disclosure.

Referring to FIG. 6, the method for converting the power of the fuel cell for power generation may include linking (S610) current to a system or load to reduce an OCV of the fuel cell before power generation of the fuel cell is started, after the fuel cell is started, and converting and supplying (S620) power generated by means of the fuel cell to the system or load.

The linking (S610) of the current to the system or load to reduce the OCV of the fuel cell before the power generation of the fuel cell is started, after the fuel cell is started, may be performed by a controller.

As an example, the linking (S610) of the current to the system or load to reduce the OCV of the fuel cell before the power generation of the fuel cell is started, after the fuel cell is started, may include checking, by the controller, a state of the system or load, before linking the current to the system or load, and linking, by the controller, the current to the system or load, when it is determined that there is no abnormality in the system or load.

As an example, the linking (S610) of the current to the system or load to reduce the OCV of the fuel cell before the power generation of the fuel cell is started, after the fuel cell is started, may include monitoring, by the controller, the OCV of the fuel cell and increasing, by the controller, current linked to the system or load such that the OCV of the fuel cell is less than a reference voltage.

As an example, the linking (S610) of the current to the system or load to reduce the OCV of the fuel cell before the power generation of the fuel cell is started, after the fuel cell is started, may include linking, by the controller, the current to the system or load by controlling, by the controller, a switching element connected with an input terminal and an output terminal of a power converter to be turned on.

As an example, the linking of the current to the system or load by the controller by controlling, by the controller, the switching element connected with the input terminal and the output terminal of the power converter to be turned on may include linking, by the controller, the current to the system or load by controlling, by the controller, a magnetic contactor connected with the input terminal and the output terminal of the power converter to be turned on.

The converting and supplying (S620) of the power generated by means of the fuel cell to the system or load may be performed by the power converter.

As an example, the converting and supplying (S620) of the power generated by means of the fuel cell to the system or load may include converting, by the power converter, DC power generated by means of the fuel cell into AC power by means of a DC/AC inverter.

As an example, the method for converting the power of the fuel cell for power generation may further include cutting off, by a first initial charge circuit connected in parallel between an output terminal of the fuel cell and the input terminal of the power converter, an inrush current from the fuel cell.

As an example, the method for converting the power of the fuel cell for power generation may further include cutting off, by a second initial charge circuit connected in series between the output terminal of the power converter and the system or load, an inrush current to the system or load.

As an example, the method for converting the power of the fuel cell for power generation may further include operating, by the controller, the first initial charge circuit to reduce an OCV of the fuel cell, after controlling the switching element connected with the input terminal of the power converter to be turned on.

As an example, the method for converting the power of the fuel cell for power generation may further include removing, by a filter device connected with the output terminal of the power converter, a noise of power output from the power converter.

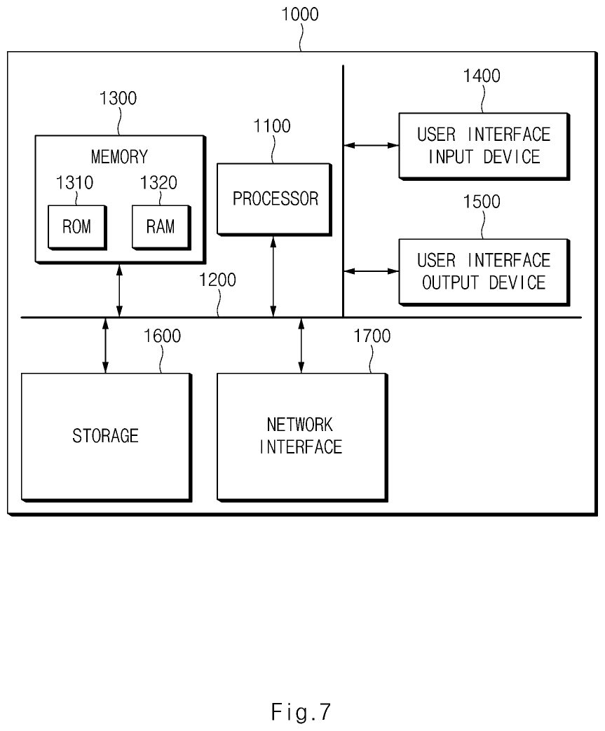

FIG. 7 is a block diagram illustrating a computing system according to an embodiment of the present disclosure.

Referring to FIG. 7, a computing system 1000 may include at least one processor 1100, a memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) 1310 and a RAM (Random Access Memory) 1320.

Thus, the operations of the method or the algorithm described in connection with the embodiments disclosed herein may be embodied directly in hardware or a software module executed by the processor 1100, or in a combination thereof. The software module may reside on a storage medium (that is, the memory 1300 and/or the storage 1600) such as a RAM, a flash memory, a ROM, an EPROM, an EEPROM, a register, a hard disk, a removable disk, and a CD-ROM.

The exemplary storage medium may be coupled to the processor 1100. The processor 1100 may read out information from the storage medium and may write information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

A description will be given of effects of the apparatus for converting the power of the fuel cell for power generation and the method thereof according to an embodiment of the present disclosure.

According to at least one of embodiments of the present disclosure, the apparatus for converting the power of the fuel cell for power generation and the method thereof may be provided to remove an open voltage of the fuel cell.

According to at least one of embodiments of the present disclosure, the apparatus for converting the power of the fuel cell for power generation and the method thereof may be provided to address a problem in which it is impossible to control an open voltage, because a stack and a load (a system) are connected one to one in the fuel cell for power generation.

According to at least one of embodiments of the present disclosure, the apparatus for converting the power of the fuel cell for power generation and the method thereof may be provided to control an open circuit voltage (OCV) of a fuel cell stack without a separate battery.

According to at least one of embodiments of the present disclosure, the apparatus for converting the power of the fuel cell for power generation and the method thereof may be provided to minimize heating due to a resistor to remove an open voltage of the fuel cell.

According to at least one of embodiments of the present disclosure, the apparatus for converting the power of the fuel cell for power generation and the method thereof may be provided to prevent performance and life of the fuel cell from being reduced.

In addition, various effects ascertained directly or indirectly through the present disclosure may be provided.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

Therefore, embodiments of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

1. An apparatus for converting power of a fuel cell for power generation, the apparatus comprising:
a power converter configured to convert and supply power generated by the fuel cell to a system or load; and
a controller configured to link current to the system or load to reduce an open circuit voltage (OCV) of the fuel cell before power generation of the fuel cell is started, after the fuel cell is started.

2. The apparatus of claim 1, wherein the controller checks a state of the system or load, before linking the current to the system or load and links the current to the system or load, when it is determined that there is no abnormality in the system or load.

3. The apparatus of claim 1, wherein the controller monitors the OCV of the fuel cell and increases current linked to the system or load such that the OCV of the fuel cell is less than a reference voltage.

4. The apparatus of claim 1, wherein the controller links the current to the system or load by controlling a switching element connected with an input terminal and an output terminal of the power converter to be turned on.

5. The apparatus of claim 1, further comprising:
a first initial charge circuit connected in parallel between an output terminal of the fuel cell and an input terminal of the power converter and configured to cut off an inrush current from the fuel cell.

6. The apparatus of claim 1, further comprising:
a second initial charge circuit connected in series between an output terminal of the power converter and the system or load and configured to cut off an inrush current to the system or load.

7. The apparatus of claim 5, wherein the controller operates the first initial charge circuit to reduce the OCV of the fuel cell, after controlling a switching element connected with the input terminal of the power converter to be turned on.

8. The apparatus of claim 1, wherein the power converter includes:
a direct current/alternating current (DC/AC) inverter configured to convert DC power generated by the fuel cell into AC power.

9. The apparatus of claim 1, further comprising:
a filter device connected with an output terminal of the power converter and configured to remove a noise of power output from the power converter.

10. The apparatus of claim 4 or 7, wherein the switching element includes a magnetic contactor (MC).

11. A method for converting power of a fuel cell for power generation, the method comprising:
linking, by a controller, a current to a system or load to reduce an OCV of the fuel cell before power generation of the fuel cell is started, after the fuel cell is started; and
converting and supplying, by a power converter, power generated by the fuel cell to the system or load.

12. The method of claim 11, wherein the linking of the current to the system or load to reduce the OCV of the fuel cell by the controller includes:
checking, by the controller, a state of the system or load, before linking the current to the system or load; and
linking the current to the system or load, when it is determined that there is no abnormality in the system or load.

13. The method of claim 11, wherein the linking of the current to the system or load to reduce the OCV of the fuel cell by the controller includes:
monitoring, by the controller, the OCV of the fuel cell; and
increasing, by the controller, current linked to the system or load such that the OCV of the fuel cell is less than a reference voltage.

14. The method of claim 11, wherein the linking of the current to the system or load to reduce the OCV of the fuel cell by the controller includes:
linking, by the controller, the current to the system or load by controlling, by the controller, a switching element connected with an input terminal and an output terminal of the power converter to be turned on.

15. The method of claim 11, further comprising:
cutting off, by a first initial charge circuit connected in parallel between an output terminal of the fuel cell and an input terminal of the power converter, an inrush current from the fuel cell.

16. The method of claim 11, further comprising:
cutting off, by a second initial charge circuit connected in series between an output terminal of the power converter and the system or load, an inrush current to the system or load.

17. The method of claim 15, further comprising:
operating the first initial charge circuit to reduce the OCV of the fuel cell, after controlling a switching element connected with the input terminal of the power converter to be turned on.

18. The method of claim 11, wherein the converting and supplying of the power generated by the fuel cell to the system or load by the power converter includes:
converting, by the power converter, DC power generated by the fuel cell into AC power by a DC/AC inverter.

19. The method of claim 11, further comprising:
removing, by a filter device connected with an output terminal of the power converter, a noise of power output from the power converter.

20. The method of claim 14, wherein the linking of the current to the system or load by the controller by controlling, by the controller, the switching element connected with the input terminal and the output terminal of the power converter to be turned on includes:
linking, by the controller, the current to the system or load by controlling, by the controller, a magnetic contactor (MC) connected with the input terminal and the output terminal of the power converter to be turned on.
